(19) United States
(12) Patent Application Publication
(10) Pub. No.: US 2014/0014990 A1
(43) Pub. Date: Jan. 16, 2014

(54) LIGHT-EMITTING DEVICE PACKAGES AND METHODS OF MANUFACTURING THE SAME

(71) Applicant: SAMSUNG ELECTRONICS CO., LTD., Suwon-Si (KR)

(72) Inventors: Jun-youn KIM, Hwaseong-si (KR); Jae-kyun KIM, Hwaseong-si (KR); Joo-sung KIM, Seongnam-si (KR); Moon-seung YANG, Hwaseong-si (KR); Su-hee CHAE, Suwon-si (KR); Young-jo TAK, Hwaseong-si (KR); Hyun-gi HONG, Suwon-si (KR)

(73) Assignee: SAMSUNG ELECTRONICS CO., LTD., Suwon-Si (KR)

(21) Appl. No.: 13/835,921

(22) Filed: Mar. 15, 2013

(30) Foreign Application Priority Data
Jul. 12, 2012 (KR) 10-2012-0076286

(51) Int. Cl. H01L 33/58

(52) U.S. Cl. CPC H01L 33/58
USPC 257/98; 438/29

(57) ABSTRACT

Lights-emitting device (LED) packages, and methods of manufacturing the same, include at least one light-emitting structure. The at least one light-emitting structure includes a first compound semiconductor layer, an active layer, and a second compound semiconductor layer that are sequentially stacked, at least one first metal layer connected to the first compound semiconductor layer, a second metal layer connected to the second compound semiconductor layer, a substrate having a conductive bonding layer on a first surface of the substrate, and a bonding metal layer configured for eutectic bonding between the at least one first metal layer and the conductive bonding layer.

### CROSS-REFERENCE TO RELATED APPLICATION

This application claims the benefits of priority under 35 U.S.C. §119 from Korean Patent Application No. 10-2012-0076286, filed on Jul. 12, 2012, in the Korean Intellectual Property Office, the disclosure of which is incorporated herein by reference in its entirety.

### BACKGROUND

1. Field

The present disclosure relates to light-emitting device packages and methods of manufacturing the light-emitting device packages.

2. Description of the Related Art

In general, light-emitting device (LED) packages are widely used in liquid crystal display (LCD) backlight units, display apparatuses, illumination apparatuses, and the like. For example, LED packages that emit visible light are used as light sources having a variety of applications such as traffic lights, view illumination, etc. In addition, because packaging costs occupies a major portion of manufacturing costs of LED packages, research into a wafer level package (WLP) that mounts an LED on a silicon substrate and covers a phosphor, and a lens on the LED has been recently conducted as a method of reducing the packaging costs. Also, an efficiency of LED packages may be improved by improving a package structure.

### SUMMARY

Provided are light-emitting device packages and methods of manufacturing the light-emitting device packages.

According to example embodiments, a light-emitting device (LED) package including at least one light-emitting structure, wherein the at least one light-emitting structure includes a first compound semiconductor layer, an active layer, and a second compound semiconductor layer sequentially stacked, at least one first metal layer connected to the first compound semiconductor layer, a second metal layer connected to the second compound semiconductor layer, a substrate having a conductive bonding layer on a first surface of the substrate, and a bonding metal layer configured for eutectic bonding between the at least one first metal layer and the conductive bonding layer.

The at lest one first metal layer may be extend through the second compound semiconductor layer and the active layer. One end portion of the at least one first metal layer may be buried in the first compound semiconductor layer.

The at least one light-emitting device may include a plurality of the at least one first metal layer. The plurality of first metal layers may be connected to each other by a first metal connection layer. The bonding metal layer may be between the first metal connection layer and the conductive bonding layer.

An eutectic bond may be between the bonding metal layer and the conductive bonding layer. The bonding metal layer may include an eutectic alloy. The eutectic alloy may be an Au—Sn alloy or an Cu—Sn alloy.

The at least one light-emitting structure may further include a first pad and a second pad formed on a second surface of the substrate, a first conductive layer in a first via hole extending through the substrate, wherein the first conductive layer connects the first pad and the conductive bonding layer, and a second conductive layer in a second via hole extending through the substrate and the conductive bonding layer, wherein the second conductive layer connects the second pad and the second metal layer. An insulation layer may be on each side walls of the first and second via holes. The substrate may include a silicon substrate.

The LED package may further include a phosphor layer on the at least one light-emitting structure, and a lens covering the at least one light-emitting structure on which the phosphor layer is on.

The LED package may further include a plurality of the at least one light-emitting structure, a plurality of phosphor layers each on one of the plurality of light-emitting structures; and a plurality of lens each covering one of the plurality of light-emitting structures on which the plurality of phosphor layers are on.

The LED package may further include a plurality of the at least one light-emitting structure, a plurality of phosphor layers each on one of the plurality of light-emitting structures, and a lens covering the plurality of light-emitting structures on which the plurality of phosphor layers are on.

According to other example embodiments, a method of manufacturing a light-emitting device (LED) package includes sequentially forming a first compound semiconductor layer, an active layer, and a second compound semiconductor layer on a growth substrate, forming at least one first metal layer extending through the second compound semiconductor layer and the active layer wherein one end portion of the at least one first metal layer is buried in the first compound semiconductor layer, forming a second metal layer connected to the second compound semiconductor layer; forming a bonding metal layer connected to the at least one first metal layer, preparing a substrate on which a conductive bonding layer is formed on a first surface of the substrate, eutectic bonding the bonding metal layer to the conductive bonding layer, and removing the growth substrate from the first compound semiconductor layer.

Forming the at least one first metal layer may include forming a plurality of the at least one first metal layer and forming a first metal connection layer connecting the plurality of first metal layers to each other. The bonding metal layer may be connected to the plurality of first metal layers. The bonding metal layer bonded to the conductive bonding layer may include an eutectic alloy.

The method may further include forming a first via hole extending through the substrate, forming a first conductive layer in the first via hole, wherein the first conductive layer is connected to the conductive bonding layer, forming a second via hole extending through the substrate and the conductive bonding layer, forming a second conductive layer in the second via hole, wherein the second conductive layer is connected to the second metal layer, disposing a first pad on the second surface of the substrate and connected to the first conductive layer, and disposing a second pad on the second surface of the substrate and connected to the second conductive layer.

The method may further include forming an insulation layer on each side walls of the first and second via holes.

The method may further include forming a phosphor layer on the first compound semiconductor layer, and forming a lens covering the phosphor layer.

### BRIEF DESCRIPTION OF THE DRAWINGS

Example embodiments will be more clearly understood from the following detailed description taken in conjunction with the accompanying drawings. FIGS. 1-14 represent non-limiting, example embodiments as described herein:

FIG. 1 is a cross-sectional view illustrating a light-emitting device (LED) package according to example embodiments;

FIGS. 2 through 12 are cross-sectional views for explaining a method of manufacturing the LED package of FIG. 1, according to example embodiments;

FIG. 13 is a cross-sectional view illustrating an LED package according to example embodiments; and

FIG. 14 is a cross-sectional view illustrating an LED package according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present disclosure relates to light-emitting device packages and methods of manufacturing the light-emitting device packages.

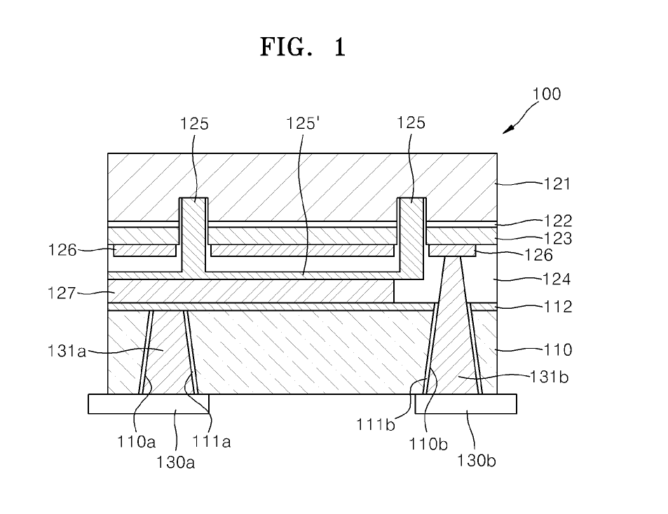

FIG. 1 is a cross-sectional view illustrating a light-emitting device (LED) package according to example embodiments.

Referring to FIG. 1, a LED package according to example embodiments include one or more light-emitting structures 100. One light-emitting structure 100 will now be exemplarily described below. The light-emitting structure 100 includes a first compound semiconductor layer 121, an active layer 122, and a second compound semiconductor layer 123 that are sequentially stacked, one or more first metal layers 125 disposed connected to the first compound semiconductor layer 121, a second metal layer 126 disposed connected to the second compound semiconductor layer 123, a substrate 110 on which a conductive bonding layer 112 is formed on a first surface, and a bonding metal layer 127 configured for eutectic bonding disposed between the first metal layer 125 and the conductive bonding layer 112. The first compound semiconductor layer 121 and the second compound semiconductor layer 123 may be n- and p-type compound semiconductor layers, respectively. For example, the first compound semiconductor layer 121 and the second compound semiconductor layer 123 may be an n-GaN layer and a p-GaN layer, respectively, but are not limited thereto. The first compound semiconductor layer 121 and the second compound semiconductor layer 123 may include various other compound semiconductor materials. In addition, although not shown in FIG. 1, a top surface of the first compound semiconductor layer 121 may have a desired roughness by surface treatment such that light generated by the active layer 122 may be further uniformly emitted to the outside through the first compound semiconductor layer 121.

The one or more first metal layers 125 may be buried in the first compound semiconductor layer 121 through the second compound semiconductor layer 123 and the active layer 122. In this regard, the first metal layers 125 may be n-type electrodes. Although the first metal layers 125 may include, for example, Al, this is merely exemplary, and the first metal layers 125 may include various other metal materials. In addition, although FIG. 1 shows the two first metal layers 125, the number of first metal layers 125 may be one or three or more. In this regard, in a case where the number of first metal layers 125 is plural, the plurality of first metal layers 125 may be connected to each other by a first metal connection layer 125′. The first metal connection layer 125′ may be formed of the same materials as the first metal layers 125 but is not necessarily limited thereto.

The second metal layer 126 is formed on a bottom surface of the second compound semiconductor layer 123. In this regard, the second metal layer 126 may be a p-type electrode. Although the second metal layer 126 may include, for example, Ag, this is merely exemplary, and the second metal layer 126 may include various other metal materials. The second metal layer 126 on the bottom surface of the second compound semiconductor layer 123 may be formed to surround the one or more first metal layers 125. In this regard, the first metal layers 125 and the first metal connection layer 125′ may be insulated from the second metal layer 126 by an insulation layer 124. Although the insulation layer 124 may include, for example, a silicon oxide, this is merely exemplary, and the insulation layer 124 may include various other insulation materials.

The bonding metal layer 127 may be disposed to connect to the one or more first metal layers 125. In the case where the number of first metal layers 125 is plural, the bonding metal layer 127 may be disposed to contact the first metal connection layer 125′ that connects the plurality of first metal layers 125 to each other. The bonding metal layer 127 is bonded with the conductive bonding layer 112 by eutectic bonding, and may include an eutectic alloy. In this regard, the eutectic alloy may include, for example, Au—Sn alloy, Cu—Sn alloy, etc., but is not limited thereto. The eutectic alloy may include various other materials.

The conductive bonding layer 112 is disposed on a bottom surface of the bonding metal layer 127. The substrate 110 is disposed on a bottom surface of the conductive bonding layer 112. Eutectic bonding may be performed between the conductive bonding layer 112 and the bonding metal layer 127 as will be described below. The conductive bonding layer 112 may include, for example, Au, but is not limited thereto. The conductive bonding layer 112 may include Cu, or various other conductive materials. The substrate 110 may use, for example, a silicon substrate, but is not limited thereto. The substrate 110 may use a substrate formed of various other materials.

First and second pads 130a and 130b are disposed on a bottom surface of the substrate 110. The first pad 130a may be connected to the conductive bonding layer 112 by a first conductive layer 131a. The second pad 130b may be connected to the second metal layer 126 by a second conductive layer 131b. To this end, a first via hole 110a is formed to pass through the substrate 110. The first conductive layer 131a is formed in the first via hole 110a. A second via hole 110b is formed to pass (or, extend) through the substrate 110, the conductive bonding layer 112, and the insulation layer 124. The second conductive layer 131b is formed in the second via hole 110b. The first and second conductive layers 131a and 131b may include, for example, Cu or Ag, etc., but are not limited thereto. The first and second conductive layers 131a and 131b may include various other conductive materials. An insulation layer 111a for insulating the substrate 110 and the first conductive layer 131a is formed on side walls of the first via hole 110a to contact the substrate 110. An insulation layer 111b for insulating the substrate 110, the conductive bonding layer 112, and the second conductive layer 131b is formed on side walls of the second via hole 110b to contact the substrate 110 and the conductive bonding layer 112. Although the insulation layers 111a and 111b may include, for example, silicon oxides, this is merely exemplary. The insulation layers 111a and 111b may include various other insulation materials. Although not shown in FIG. 1, a phosphor layer may be formed on the light-emitting structure 100 (more specifically, on the first compound semiconductor layer 121), and a lens may be further disposed to cover the phosphor layer and the light-emitting structure 100. In addition, although the conductive bonding layer 112 is formed on the entire top surface of the substrate 110, the conductive bonding layer 112 may not be formed on the top surface of the substrate 110 in which the second via hole 110b is formed.

In the above-described structure, current supplied to the first pad 130a is injected into the first compound semiconductor layer 121 through the first conductive layer 131a, the conductive bonding layer 112, the bonding metal layer 127, and the first metal layer 125. Current supplied to the second pad 130b is injected into the second compound semiconductor layer 123 through the second conductive layer 131b and the second metal layer 126. Accordingly, light of a desired color generated by the active layer 122 is emitted to the outside through the top surface of the first compound semiconductor layer 121.

As described above, the LED package has a structure capable of securing a larger light-emitting area, thereby improving light-emitting efficiency. Thus, the number of light-emitting structures required by the LED package may be reduced, thereby reducing manufacturing cost.

A method of manufacturing an LED package, according to example embodiments will now be described.

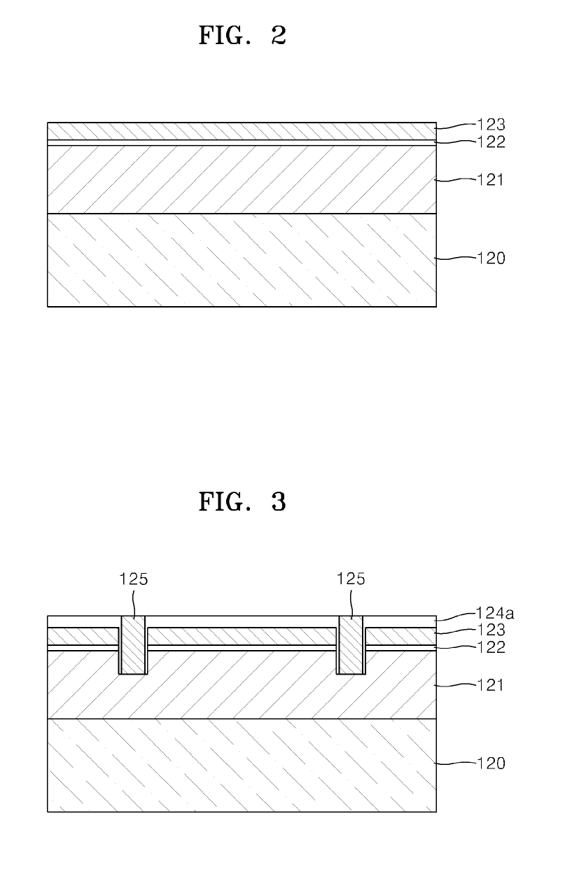

FIGS. 2 through 12 are cross-sectional views for explaining a method of manufacturing the LED package of FIG. 1, according to example embodiments. A case in which the LED package includes one light-emitting structure will now be described below.

Referring to FIG. 2, a growth substrate 120 is prepared. The growth substrate 120 may use a silicon substrate or a sapphire substrate but is not limited thereto. Next, the first compound semiconductor layer 121, the active layer 122, and the second compound semiconductor layer 123 are sequentially grown on the growth substrate 120 by using, for example, metal-organic chemical vapor deposition (MOCVD) or molecular beam epitaxy (MBE). In this regard, the first compound semiconductor layer 121 and the second compound semiconductor layer 123 may be n- and p-type compound semiconductor layers, respectively. For example, the first compound semiconductor layer 121 and the second compound semiconductor layer 123 may be an n-GaN layer and a p-GaN layer, respectively, but are not limited thereto.

Referring to FIG. 3, the second compound semiconductor layer 123, the active layer 122, and the first compound semiconductor layer 121 are sequentially etched, and then a first insulation layer 124a is formed to cover an etched surface and a surface of the second compound semiconductor layer 123. Thereafter, the first insulation layer 124a is patterned, and then the first metal layers 125 are formed to connect to the first compound semiconductor layer 121. The first insulation layer 124a may include, for example, a silicon oxide, but is not limited thereto. Accordingly, lower portions of the first metal layers 125 may be buried in the first compound semiconductor layer 121 through the second compound semiconductor layer 123 and the active layer 122. The first metal layer 125 may be an n-type electrode. Although the first metal layers 125 may include, for example, Al, the first metal layers 125 may include various other metal materials. In addition, although FIG. 3 shows the two first metal layers 125, the number of first metal layers 125 may be one or three or more.

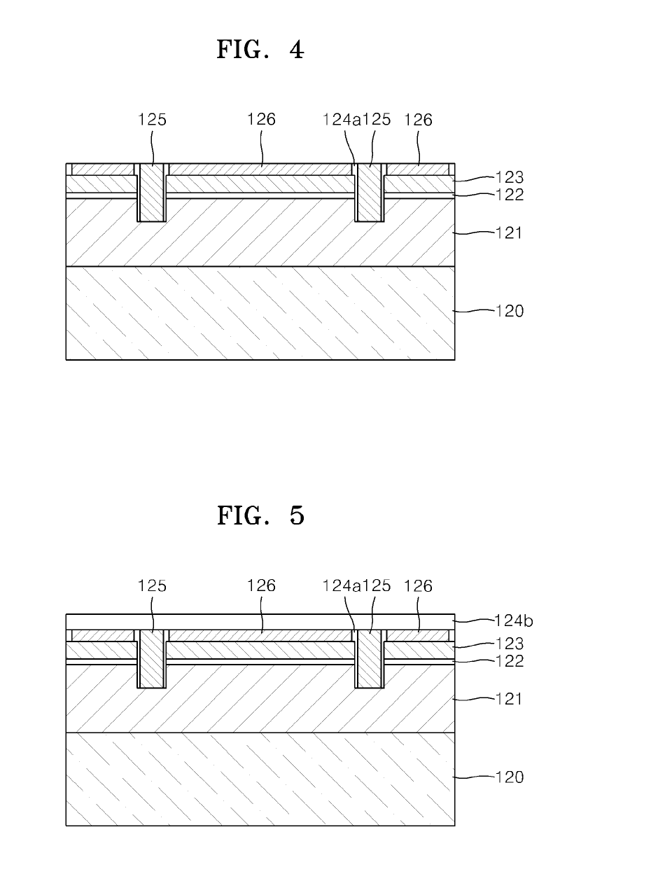

Referring to FIG. 4, the first insulation layer 124a is patterned, and then the second metal layer 126 is deposited on a top surface of the second compound semiconductor layer 123. The second metal layer 126 may be a p-type electrode. The second metal layer 126 may include, for example, Ag, but this is merely exemplary. The second metal layer 126 may include various other metal materials. The second metal layer 126 may be formed surrounding the first metal layers 125. In this regard, the first metal layers 125 and the second metal layer 126 may be insulated from each other by the first insulation layer 124a.

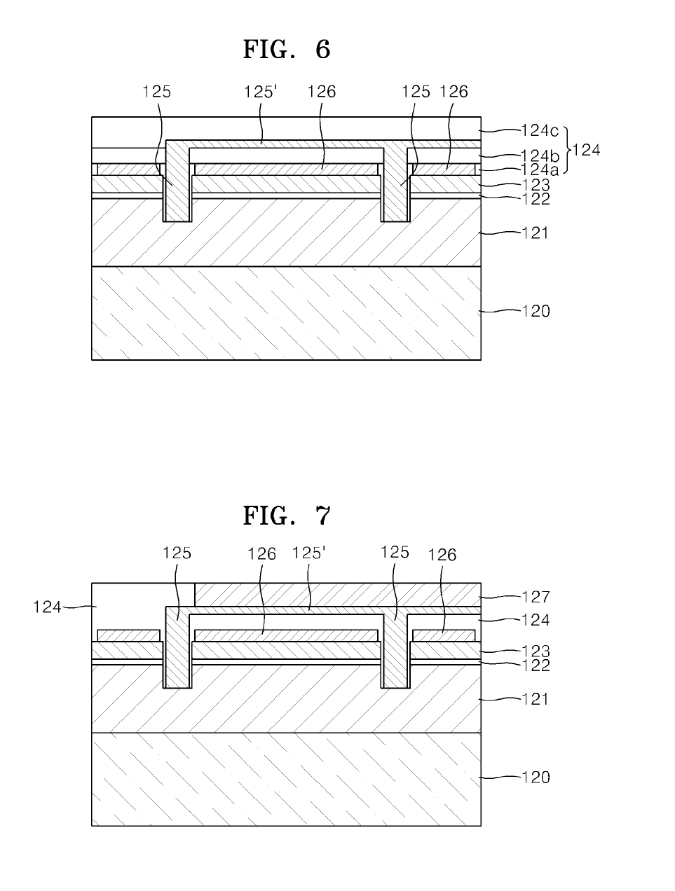

Referring to FIG. 5, a second insulation layer 124b may be formed on top surfaces of the first insulation layer 124a and the second metal layer 126. In this regard, the second metal layer 124b may include the same material as the first insulation layer 124a but is not limited thereto.

Referring to FIG. 6, the first metal connection layer 125′ that connects the first metal layers 125 is formed. More specifically, the second insulation layer 124b is etched, and then a select metal is deposited thereon, and the first metal connection layer 125′ that connects upper portions of the first metal layers 125 is formed. In this regard, the first metal connection layer 125′ may include the same material as the first metal layers 125 but is not limited thereto. A third insulation layer 124c is formed to cover the first metal connection layer 125′ and the second insulation layer 124b. In this regard, the third insulation layer 124c may include the same material as the first and second insulation layers 124a and 124b but is not limited thereto. The sequentially stacked first through third insulation layers 124a, 124b, and 124c are referred to as an insulation layer 124 below.

Referring to FIG. 7, a top surface of the insulation layer 124 is etched to expose a top surface of the first metal connection layer 125′, and then the bonding metal layer 127 is deposited thereon. In this regard, the bonding metal layer 127 is used for eutectic bonding with the conductive bonding layer 112 that will be described below.

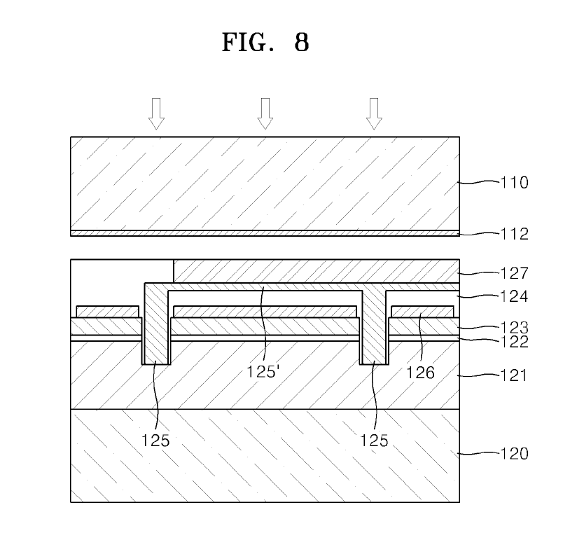

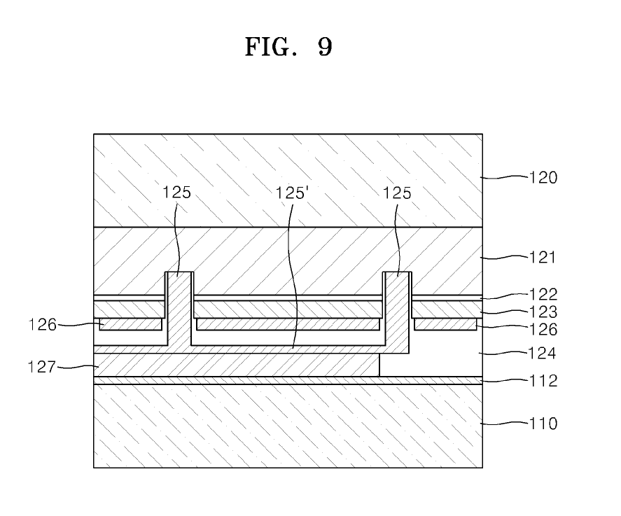

Referring to FIG. 8, the substrate 110 on which the conductive bonding layer 112 is formed is prepared. The conductive bonding layer 112 may be disposed on a first surface (a bottom surface of the substrate 110 in FIG. 8) of the substrate 110. In this regard, the substrate 110 may use a silicon substrate but is not limited thereto. Thereafter, the conductive bonding layer 112 formed on the first surface of the substrate 110 is bonded to the bonding metal layer 127 by eutectic bonding. Such eutectic bonding may be performed, for example, at approximately about 200° C. and about 400° C. but this is merely exemplary. A eutectic bonding temperature may differ according to materials included in the bonding metal layer 127 and the conductive bonding layer 112. FIG. 9 shows an upside down state of a structure in which the bonding metal layer 127 and the conductive bonding layer 112 are bonded to each other by eutectic bonding in FIG. 8. Thereafter, the growth substrate 120 formed on the top surface of the first compound semiconductor layer 121 is removed. In addition, after the growth substrate 120 is removed, surface treatment may be performed on the top surface of the first compound semiconductor layer 121 to have a desired roughness.

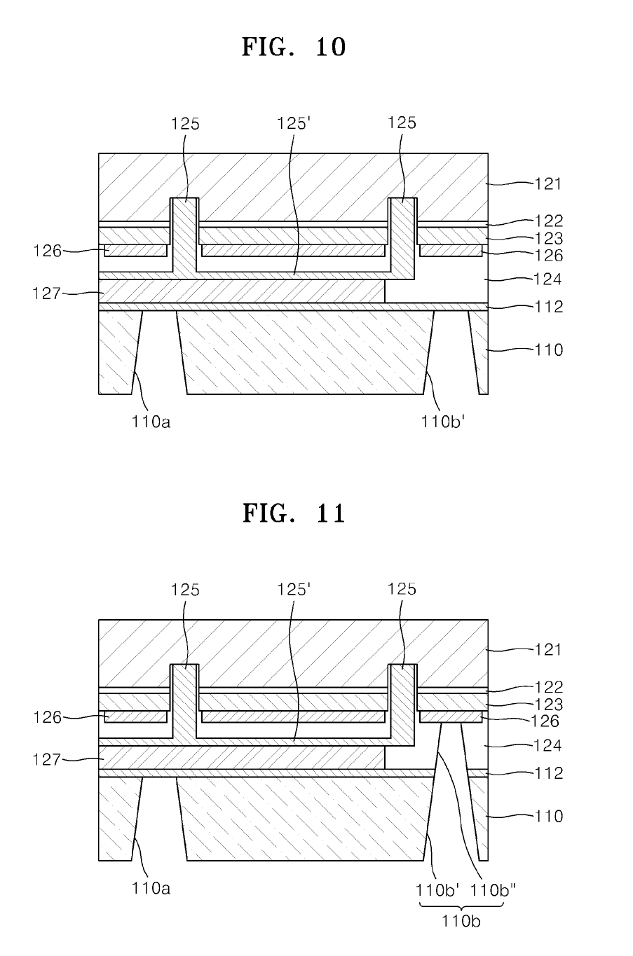

Referring to FIG. 10, the first via hole 110a and a lower second via hole 110b′ are formed in the substrate 110. The first via hole 110a and the lower second via hole 110b′ may be formed by etching a second surface (a bottom surface of the substrate 110 in FIG. 10) of the substrate 110 until the conductive bonding layer 112 is exposed.

Referring to FIG. 11, an upper second via hole 110b″ connected to the lower second via hole 110b′ is formed by etching the conductive bonding layer 112 and the insulation layer 124 until the second metal layer 126 is exposed. Accordingly, the first via hole 110a may be formed in one side of the substrate 110 to pass through the substrate 110 and expose the conductive bonding layer 112, and the second via hole 110b may be formed in the other side of the substrate 110 to pass through the substrate 110, the conductive bonding layer 112, and the insulation layer 124 and expose the second metal layer 126.

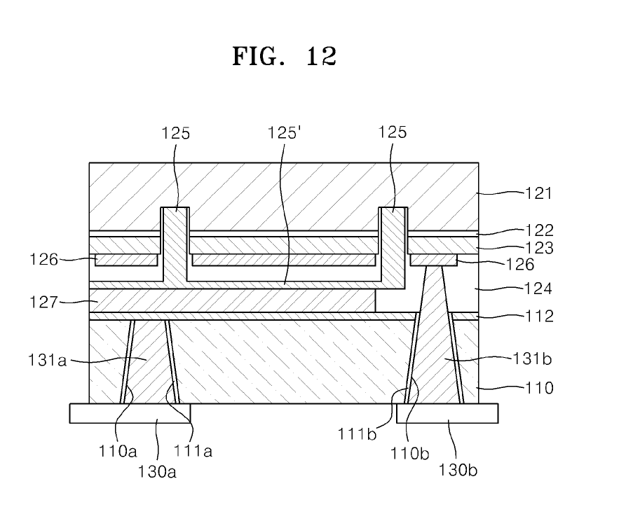

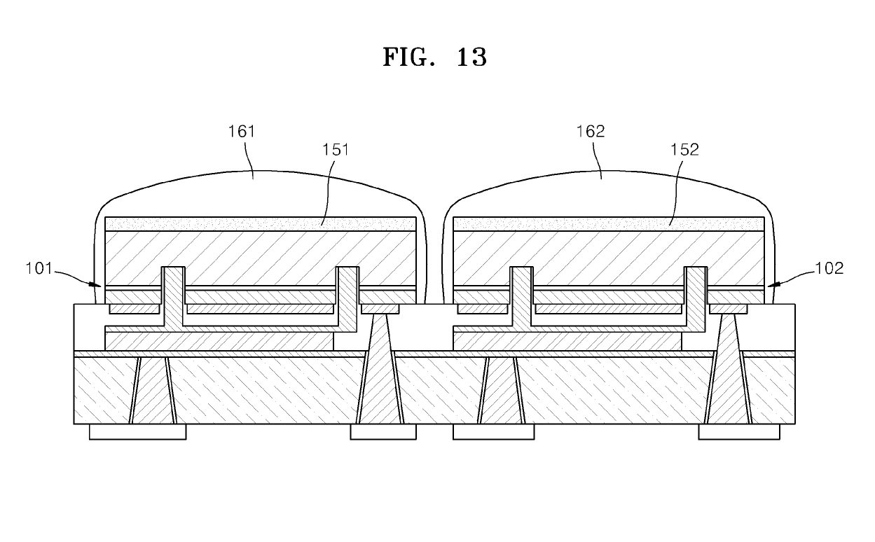

Referring to FIG. 12, the first and second conductive layers 131a and 131b are formed in the first and second via holes 110a and 110b, respectively, and then the first and second pads 130a and 130b electrically connected to the first and second conductive layers 131a and 131b, respectively, are formed on the second surface (the bottom surface of the substrate 110 in FIG. 12) of the substrate 110. In this regard, the first and second conductive layers 131a and 131b may be formed by filling materials having high electric conductivity and thermal conductivity in the first and second via holes 110a and 110b, respectively. The first and second conductive layers 131a and 131b may include, for example, a metal paste or metal plating, but are not limited thereto. The first and second conductive layers 131a and 131b may include other materials. In addition, an insulation layer 111a may be formed on side walls of the first via hole 110a to contact the substrate 110 in order to insulate the first conducive layer 131a from the substrate 110. An insulation layer 111b may be formed on side walls of the second via hole 110b to contact the substrate 110 and the conductive bonding layer 112 in order to insulate the second conducive layer 131b from the substrate 110 and the conductive bonding layer 112. The first pad 130a, the first conductive layer 131a, the conductive bonding layer 112, the bonding metal layer 127, and the first metal layer 125 are electrically connected to each other. The second pad 130b, the second conductive layer 131b, and the second metal layer 126 may be electrically connected to each other. Accordingly, the light-emitting structure (100 of FIG. 1) of the LED package is completely manufactured. In addition, although not shown, a phosphor layer is formed on the light-emitting structure (more specifically, on the first compound semiconductor layer 121), and then and a lens may be further disposed to cover the phosphor layer and the light-emitting structure 100. In addition, although the conductive bonding layer 112 is formed on the entire first surface of the substrate 110 as described above, the conductive bonding layer 112 may not be formed on the first surface of the substrate 110 in which the second via hole 110b is to be formed. In this case, an etching process for forming the second via hole 110b may be easier to perform.

According to the above-described method of manufacturing the LED package, according to example embodiments, an expensive metal (e.g., Au) may not be used, and the LED package may be manufactured by using a WLP that uses eutectic bonding, thereby reducing the manufacturing cost of the LED package.

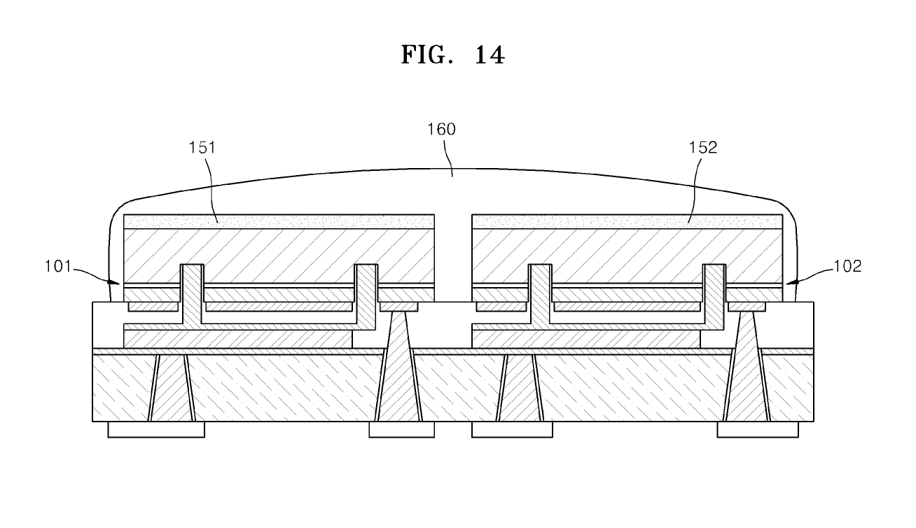

FIG. 13 is a cross-sectional view illustrating an LED package according to example embodiments.

Referring to FIG. 13, the LED package according to example embodiments includes first and second light-emitting structures 101 and 102. In this regard, the first and second light-emitting structures 101 and 102 are the same as the light-emitting structure 100 of FIG. 1, and thus redundant descriptions thereof are omitted here. A first phosphor layer 151 may be formed on the first light-emitting structure 101. A second phosphor layer 151 may be formed on the second light-emitting structure 102. In this regard, the first and second phosphor layers 151 and 152 may be formed on the first and second light-emitting structures 101 and 102, respectively, in various shapes.

A first lens 161 may be formed to cover the first phosphor layer 151 and the first light-emitting structure 101. A second lens 162 may be formed to cover the second phosphor layer 152 and the second light-emitting structure 102. In addition, the LED package of FIG. 13 exemplarily includes the two light-emitting structures 101 and 102, and may include three or more light-emitting structures.

FIG. 14 is a cross-sectional view illustrating an LED package according to example embodiments.

Referring to FIG. 14, the LED package according to example embodiments includes the first and second light-emitting structures 101 and 102. In this regard, the first and second light-emitting structures 101 and 102 are the same as the light-emitting structure 100 of FIG. 1, and thus redundant descriptions thereof are omitted here. The first phosphor layer 151 may be formed on the first light-emitting structure 101. The second phosphor layer 152 may be formed on the second light-emitting structure 102. A lens 160 may be disposed to entirely cover the first phosphor layer 151 and the first light-emitting structure 101, and the second phosphor layer 152 and the second light-emitting structure 102. In addition, the LED package of FIG. 14 exemplarily includes the two light-emitting structures 101 and 102, and may include three or more light-emitting structures.

As described above, according to example embodiments, the LED package has a structure capable of securing a larger light-emitting area, thereby improving light-emitting efficiency. Thus, the number of light-emitting structures required by the LED package may be reduced, thereby reducing manufacturing cost. Also, a process of manufacturing the LED package may not use an expensive metal such as Au, and the LED package may be manufactured by using a WLP that uses eutectic bonding, thereby reducing the manufacturing costs of the LED package.

The foregoing is illustrative of example embodiments and is not to be construed as limiting thereof. Although a few example embodiments have been described, those skilled in the art will readily appreciate that many modifications are possible in example embodiments without materially departing from the novel teachings. Accordingly, all such modifications are intended to be included within the scope of the disclosure as defined in the claims. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A light-emitting device (LED) package, comprising:
at least one light-emitting structure,
wherein the at least one light-emitting structure includes,
a first compound semiconductor layer, an active layer, and a second compound semiconductor layer sequentially stacked,
at least one first metal layer connected to the first compound semiconductor layer,
a second metal layer connected to the second compound semiconductor layer;
a substrate having a conductive bonding layer on a first surface of the substrate, and
a bonding metal layer configured for eutectic bonding between the at least one first metal layer and the conductive bonding layer.

2. The LED package of claim 1, wherein the at least one first metal layer extends through the second compound semiconductor layer and the active layer, and
one end portion of the at least one first metal layer is buried in the first compound semiconductor layer.

3. The LED package of claim 2, wherein the at least one light-emitting structure includes a plurality of the at least one first metal layer, and
the plurality of first metal layers are connected to each other by a first metal connection layer.

4. The LED package of claim 3, wherein the bonding metal layer is between the first metal connection layer and the conductive bonding layer.

5. The LED package of claim 1, wherein an eutectic bond is between the bonding metal layer and the conductive bonding layer.

6. The LED package of claim 5, wherein the bonding metal layer includes an eutectic alloy.

7. The LED package of claim 6, wherein the eutectic alloy is an Au—Sn alloy or an Cu—Sn alloy.

8. The LED package of claim 1, wherein the at least one light-emitting structure further includes,
a first pad and a second pad on a second surface of the substrate,
a first conductive layer in a first via hole extending through the substrate, wherein the first conductive layer connects the first pad and the conductive bonding layer, and
a second conductive layer in a second via hole extending through the substrate and the conductive bonding layer, wherein the second conductive layer connects the second pad and the second metal layer.

9. The LED package of claim 8, further comprising:
an insulation layer on side walls of the first and second via holes.

10. The LED package of claim 1, wherein the substrate is a silicon substrate.

11. The LED package of claim 1, further comprising:
a phosphor layer on the at least one light-emitting structure; and
a lens covering the at least one light-emitting structure on which the phosphor layer is on.

12. The LED package of claim 1, further comprising:
a plurality of the at least one light-emitting structure;
a plurality of phosphor layers each on one of the plurality of light-emitting structures; and
a plurality of lens each covering one of the plurality of light-emitting structures on which the plurality of phosphor layers are on.

13. The LED package of claim 1, further comprising:
a plurality of the at least one light-emitting structure;
a plurality of phosphor layers each on one of the plurality of light-emitting structures; and
a lens covering the plurality of light-emitting structures on which the plurality of phosphor layers are on.

14. A method of manufacturing a light-emitting device (LED) package, the method comprising:
sequentially forming a first compound semiconductor layer, an active layer, and a second compound semiconductor layer on a growth substrate;
forming at least one first metal layer extending through the second compound semiconductor layer and the active layer, wherein one end portion of the at least one first metal layer is buried in the first compound semiconductor layer;
forming a second metal layer connected to the second compound semiconductor layer;
forming a bonding metal layer connected to the at least one first metal layer;
preparing a substrate on which a conductive bonding layer is formed on a first surface of the substrate;
eutectic bonding the bonding metal layer to the conductive bonding layer; and
removing the growth substrate from the first compound semiconductor layer.

15. The method of claim 14, wherein forming the at least one first metal layer includes forming a plurality of the at least one first metal layer and forming a first metal connection layer connecting the plurality of first metal layers to each other; and
the bonding metal layer is connected to the plurality of first metal layers.

16. The method of claim 14, wherein the bonding metal layer bonded to the conductive bonding layer includes an eutectic alloy.

17. The method of claim 14, further comprising:
forming a first via hole extending through the substrate;
forming a first conductive layer in the first via hole, wherein the first conductive layer is connected to the conductive bonding layer;
forming a second via hole extending through the substrate and the conductive bonding layer,
forming a second conductive layer in the second via hole, wherein the second conductive layer is connected to the second metal layer;
disposing a first pad on the second surface of the substrate and connected to the first conductive layer; and
disposing a second pad on the second surface of the substrate and connected to the second conductive layer.

18. The method of claim 17, further comprising:
forming an insulation layer on each side walls of the first and second via holes.

19. The method of claim 14, further comprising:
forming a phosphor layer on the first compound semiconductor layer; and
forming a lens covering the phosphor layer.
